(19) United States
(12) Patent Application Publication
(10) Pub. No.: US 2024/0113141 A1
(43) Pub. Date: Apr. 4, 2024

(54) ELECTRONIC COMPONENT AND METHOD OF MANUFACTURING THE SAME

(71) Applicant: CANON KABUSHIKI KAISHA, Tokyo (JP)

(72) Inventor: YU KATASE, Kanagawa (JP)

(21) Appl. No.: 18/465,260

(22) Filed: Sep. 12, 2023

(30) Foreign Application Priority Data
Sep. 22, 2022 (JP) 2022-151802

(51) Int. Cl. H01L 27/146; H05K 5/03

(52) U.S. Cl. CPC H01L 27/14618; H05K 5/03; H01L 24/45

(57) ABSTRACT

An electronic component includes an electronic device and a container configured to house the electronic device. The container includes a support configured to support the electronic device, and a quartz plate having a principal plane facing the electronic device, and an angle θ formed by the principal plane and an optical axis of the quartz plate satisfies |3|°<θ<|42|° or |48|°<θ<|87|°.

### BACKGROUND OF THE INVENTION

### Field of the Invention

The present invention relates to an electronic component and a method of manufacturing the same.

### Description of the Related Art

In recent years, in an electronic component including an electronic device such as an image capturing device and a container that houses the electronic device, a stress on the electronic component has become larger along with a variety of use environments. Therefore, in the electronic component including the electronic device and the container that houses it, the container is required to be sufficiently resistant to an expected stress. The container can include a support that supports the electronic device, and a quartz plate facing the electronic device. The quartz plate can function as a low-pass filter by the birefringent characteristic. The quartz plate serving as a low-pass filter can be configured to provide a required separation width. Light that vertically enters the incident surface of the quartz plate is separated into ordinary light and extraordinary light to travel to an exit surface, and the ordinary light and the extraordinary light exit from the exit surface. The separation width is the distance between the ordinary light and the extraordinary light on the exit surface. The required separation width decreases in accordance with reduction in pixel size of the image capturing device. Since the separation width is proportional to the thickness of the quartz plate, the separation width can be decreased by decreasing the thickness of the quartz plate. However, if the thickness of the quartz plate is made too small in order to decrease the separation width, the quartz plate may be deformed or damaged when a stress is applied to the quartz plate.

Japanese Patent Laid-Open No. 2001-209008 describes an optical low-pass filter but does not consider a problem caused by a stress that can be applied to the optical low-pass filter.

### SUMMARY OF THE INVENTION

The present invention provides a technique advantageous in suppressing deformation or damage of a quartz plate caused by reduction in separation width.

One of aspects of the present invention provides an electronic component comprising an electronic device and a container configured to house the electronic device, wherein the container includes a support configured to support the electronic device, and a quartz plate having a principal plane facing the electronic device, and an angle θ formed by the principal plane and an optical axis of the quartz plate satisfies |3|°<θ<|42|° or |48|°<θ<|87|°.

Further features of the present invention will become apparent from the following description of exemplary embodiments with reference to the attached drawings.

### BRIEF DESCRIPTION OF THE DRAWINGS

FIG. 1A is a plan view schematically showing the arrangement of an electronic component according to the first embodiment;

FIG. 1B is a sectional view schematically showing the arrangement of the electronic component according to the first embodiment;

FIG. 2A is a perspective view schematically showing a quartz ingot;

FIG. 2B is a sectional view schematically showing the quartz ingot;

FIG. 3 is a view for explaining the separation characteristic of a quartz plate;

FIGS. 4A and 4B are views each schematically showing the relationship between the separation characteristic of the quartz plate and the thickness of the quartz plate;

FIGS. 5A to 5D are views showing an example of a method of cutting out the quartz plate from the quartz ingot according to the first embodiment;

FIGS. 6A to 6D are views showing an example of a method of cutting out a quartz plate from a quartz ingot according to the second embodiment;

FIG. 7 is a sectional view showing an example of a quartz plate cut out from a quartz ingot according to the third embodiment;

FIG. 8 is a sectional view showing an example of a quartz plate cut out from a quartz ingot according to the fourth embodiment;

FIG. 9 is a block diagram exemplifying an apparatus in which an electronic component is incorporated; and

FIG. 10 is a flowchart exemplifying a method of manufacturing the electronic component.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

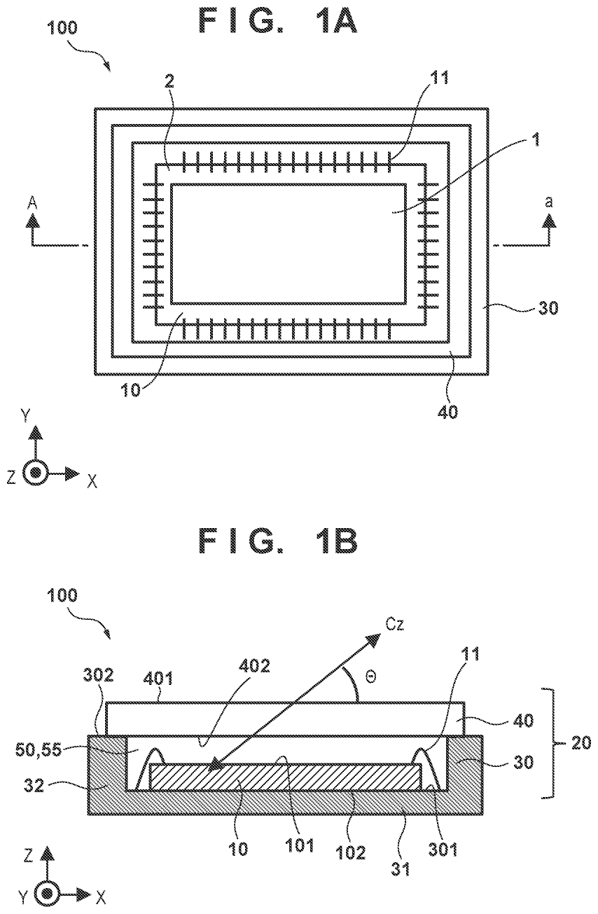

FIG. 1A is a plan view exemplarily and schematically showing the arrangement of an electronic component 100 according to the first embodiment of present disclosure. FIG. 1B is a sectional view exemplarily and schematically showing the arrangement of the electronic component 100 taken along a line A-a in FIG. 1A. In FIGS. 1A and 1B, directions are indicated in accordance with an XYZ coordinate system.

The electronic component 100 can include an electronic device 10, and a container 20 that houses the electronic device 10. The container 20 can include a support 30 that supports the electronic device 10, and a quartz plate 40 facing the electronic device 10. The support 30 can function as an open container and the quartz plate 40 can function as a lid. The container 20 formed by connecting the quartz plate 40 to the support 30 can form a sealed container but may form an unsealed container. The quartz plate 40 can include an inner surface 402 facing the electronic device 10, and an outer surface 401 that is a surface on the opposite side of the inner surface. The inner surface 402 and the outer surface 401 may be parallel to each other. The inner surface 402 may be understood as the principal plane of the quartz plate 40.

The support 30 mechanically supports the electronic device 10, and can also provide electrical connection between the electronic device 10 and another electronic device (not shown) or an electronic component. The support 30 can include a concave portion 55 that defines an internal space 50 together with the quartz plate 40. The bottom surface of the concave portion 55 can include a support surface 301 that supports the electronic device 10. The support 30 can include, for example, a plate-like portion 31 including the support surface 301, and a frame-like portion 32. The support surface 301 or the plate-like portion 31 can define the lower surface of the internal space 50. The frame-like portion 32 can define the side surface of the internal space 50. The frame-like portion 32 can be arranged to surround the side surface of the electronic device 10. From another viewpoint, the electronic device 10 can be arranged so that its side surface is surrounded by the frame-like portion 32.

The quartz plate 40 can function as an optical member. As exemplified in FIG. 1B, a rear surface 102 of the electronic device 10 can be fixed or connected to the support surface 301 of the support 30 by, for example, an adhesive. The quartz plate 40 can be fixed or connected to an upper surface 302 of the frame-like portion 32 of the support 30 by, for example, an adhesive (not shown). The quartz plate 40 can be arranged to face a front surface 101 of the electronic device 10 via part of the internal space 50.

In the example shown in FIGS. 1A and 1B, the X direction and Y direction (the X-Y plane) are parallel to the front surface 101 and the rear surface 102 of the electronic device 10, and the outer surface 401 and the inner surface 402 (principal plane) of the quartz plate 40. The Z direction is a direction perpendicular to the front surface 101, the rear surface 102, and the outer surface 401 and the inner surface 402 (principal plane) of the quartz plate 40.

The electronic device 10 and the electronic component 100 can typically have a rectangular shape in orthogonal projection to the X-Y plane. In addition, the electronic device 10 and the electronic component 100 can typically have a flat plate shape with dimensions in the X direction and the Y direction larger than that in the Z direction.

The type of the electronic device 10 is not particularly limited but can typically be an optical device. The electronic device 10 can include a primary region 1 and a secondary region 2. Typically, the primary region 1 can be arranged at the center of the electronic device 10, and the secondary region 2 can be arranged outside the primary region 1. In a case where the electronic device 10 is formed as an image capturing device such as a CCD image sensor or a CMOS image sensor, the primary region 1 serves as an image capturing region. In a case where the electronic device 10 is formed as a display device such as a liquid crystal display or an EL display, the primary region 1 serves as a display region. In the case of the image capturing device, the front surface 101 of the electronic device 10 serves as a light incident surface. The light incident surface can be formed by an outermost layer of a multilayered film provided on a semiconductor substrate having a light receiving surface. The multilayered film can include a layer having an optical function such as a color filter layer, a microlens layer, an antireflection layer, or a light-shielding layer, a layer having a mechanical function such as a planarizing layer, and a layer having a chemical function such as a passivation layer. In the secondary region 2, a driving circuit for driving a circuit or an element in the primary region 1, and a signal processing circuit for processing a signal from the circuit or the element in the primary region 1 (or a signal to the circuit or the element in the primary region 1) can be provided. If the electronic device 10 is a semiconductor device, it is easy to monolithically form such circuit. In a case where the electronic device 10 is an electronic device formed by stacking two or more electronic devices, an electronic device serving as the secondary region 2 can be stacked under an electronic device serving as the primary region 1.

The support 30 can be formed by, for example, die molding, cutting processing, stacking of plate materials, or the like. The support 30 may be a conductor such as a metal plate but is preferably an insulator. The support 30 may be a flexible substrate such as a polyimide substrate but is preferably a rigid substrate such as a glass epoxy substrate, a composite substrate, a glass composite substrate, a Bakelite substrate, or a ceramic substrate. The support 30 is particularly preferably a ceramic substrate or a glass epoxy substrate. In a case where the support 30 is a ceramic substrate, a ceramic laminate is preferably used. As a ceramic material, silicon carbide, aluminum nitride, sapphire, alumina, silicon nitride, cermet, yttria, mullite, forsterite, cordierite, zirconia, steatite, or the like can be used. In a case where the support 30 is a glass epoxy substrate, a structure in which the frame-like portion 32 is connected to a peripheral region of the substrate forming the plate-like portion 31 can be adopted to form the concave portion 55. For the frame-like portion 32, a material such as ceramic, a metal, or a resin can be used. Examples of a metal material are aluminum, an aluminum alloy, copper, a copper alloy, and an iron alloy. An iron alloy containing chromium, nickel, or cobalt, which is represented by stainless steel, is more preferable. For example, SUS430 as ferritic stainless steel, SUS304 as austenite stainless steel, 42 Alloy, or kovar can be used. Examples of a resin material are an epoxy resin, an acrylic resin, a silicone resin, and a vinyl resin. Examples of an organic material are a dry solidification-type material by solvent evaporation, a chemical reaction-type material that is cured by polymerization of molecules by light or heat, a hot melt-type material that is cured by solidification of a melted material. Typically, a photo-curable resin that is cured by ultraviolet light or visible light or a thermosetting resin that is cured by heat can be used.

Each of the electronic device 10 and the support 30 includes an electrode, and the electrode of the electronic device 10 and the electrode of the support 30 can electrically be connected by a wire 11 using, for example, gold, silver, copper, aluminum, or an alloy thereof. This enables the electronic device 10 to be electrically connected to an external circuit via an external terminal (not shown) provided in the support 30. The external terminal can be, for example, a Land Grid Array (LGA), a Pin Grid Array (PGA), a Ball Grid Array (BGA), a Leadless Chip Carrier (LCC), a lead frame, a connector, or the like. To connect the external terminal and the external circuit, for example, reflow soldering using a solder paste can be adopted. In this way, the electronic component 100 can secondarily be implemented to form an electronic module. An electronic apparatus is formed by incorporating the electronic module in a housing.

In a case where the electronic device 10 serves an image capturing device, the quartz plate 40 arranged to face the electronic device 10 includes the outer surface 401 as a surface on the light incident side and the inner surface 402 as a surface on the light exit side. Reference symbol Cz in FIG. 1B denotes the direction of the optical axis of a quartz crystal forming the quartz plate 40. Note that optical axis indicates the optical axis of a birefringent crystal, and is also called an optic axis (of a crystal). An angle θ formed by the optical axis Cz of the quartz crystal, the inner surface 402 (principal plane), and the outer surface 401 will be described later. On the outer surface 401 and the inner surface 402 of the quartz plate 40, an antireflection coating and/or infrared cut coating may be applied.

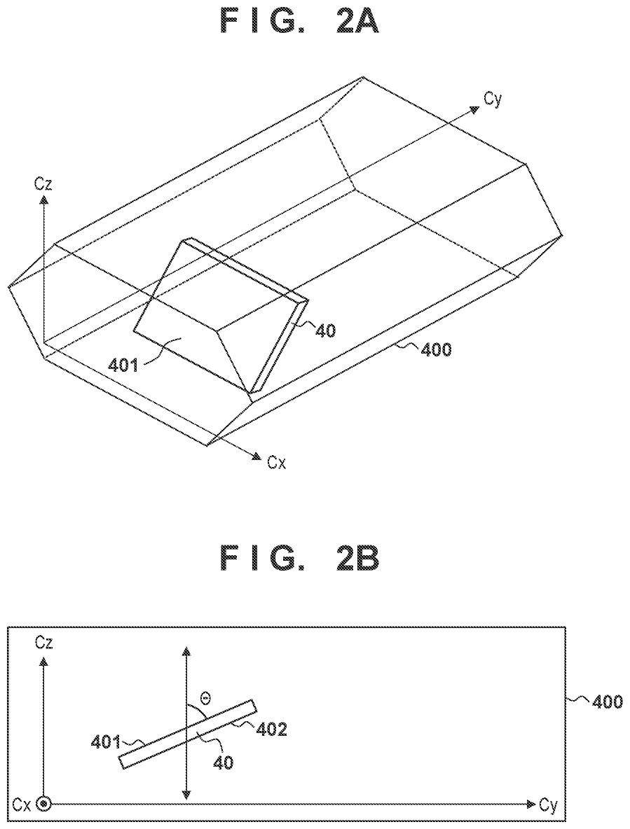

FIGS. 2A and 2B are respectively a perspective view and a sectional view schematically showing a quartz ingot 400. The quartz plate 40 can be manufactured by being cutting out from the quartz ingot 400. The Cz-axis is the optical axis of a quartz crystal forming the quartz ingot 400, and is also the crystal growing direction of the quartz ingot 400. The quartz crystal further includes a Cx-axis and a Cy-axis orthogonal to the Cz-axis, and the Cx-axis is called an electric axis and the Cy-axis is called a machine axis. The angle θ shown in FIG. 2B is an angle formed by the optical axis (Cz-axis), the outer surface 401, and the inner surface 402 (principal plane).

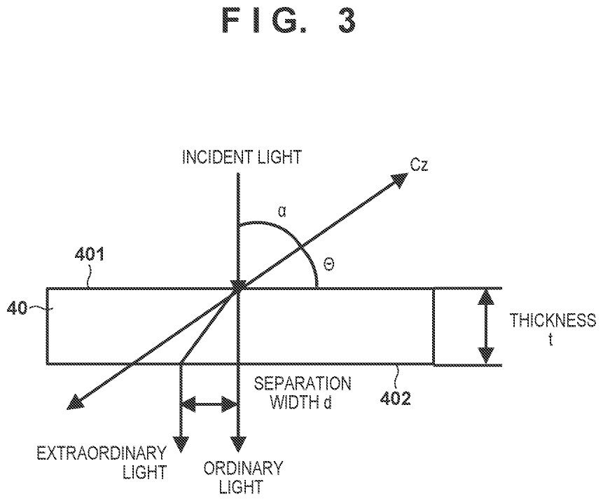

FIG. 3 is a view for explaining the separation characteristic of the quartz plate 40. Similar to θ shown in FIG. 2B, θ shown in FIG. 3 represents an angle formed by the optical axis (Cz-axis), the inner surface (principal plane) 402, and the outer surface 401. An angle α is an angle formed by the optical axis (Cz-axis) and light vertically entering the outer surface 401. The angle α can be represented by α=90°−θ. The distance between the inner surface 402 and the outer surface 401 in a direction perpendicular to the inner surface 402 (more simply, the distance between the inner surface 402 and the outer surface 401) indicates a thickness t of the quartz plate 40.

Light vertically entering the outer surface 401 (incident surface) is separated into ordinary light and extraordinary light to travel toward the inner surface 402 (exit surface). If No represents an ordinary light refractive index unique to the quartz crystal and Ne represents an extraordinary light refractive index, a separation width d can be represented by d=t×{(No²−Ne²)×tan α}/{(No²×tan²α)+Ne²}. The separation width d indicates the distance between the ordinary light and the extraordinary light on the inner surface 402 (principal plane). From this equation, when θ=α=45°, tan α=1 is obtained, thereby making it possible to obtain the maximum separation width d. That is, when θ=45°, the separation width d is decided based on only the thickness t of the quartz plate 40. The separation width d required in the specification of the electronic component 100 can be a separation width required to reduce color moiré and false color. However, as the required separation width d decreases, the thickness t of the quartz plate 40 decreases. Therefore, after the electronic component 100 is formed by fixing the quartz plate 40 to the support 30, the quartz plate 40 may be deformed or damaged (for example, cracked or peeled) when a stress is applied from an external environment. To cope with this, in this embodiment, both suppression of deformation, damage, and the like of the quartz plate 40 and suppression of occurrence of color moiré and false color are implemented by setting the thickness t of the quartz plate 40 to be equal to or more than a predetermined thickness while ensuring the required separation width d.

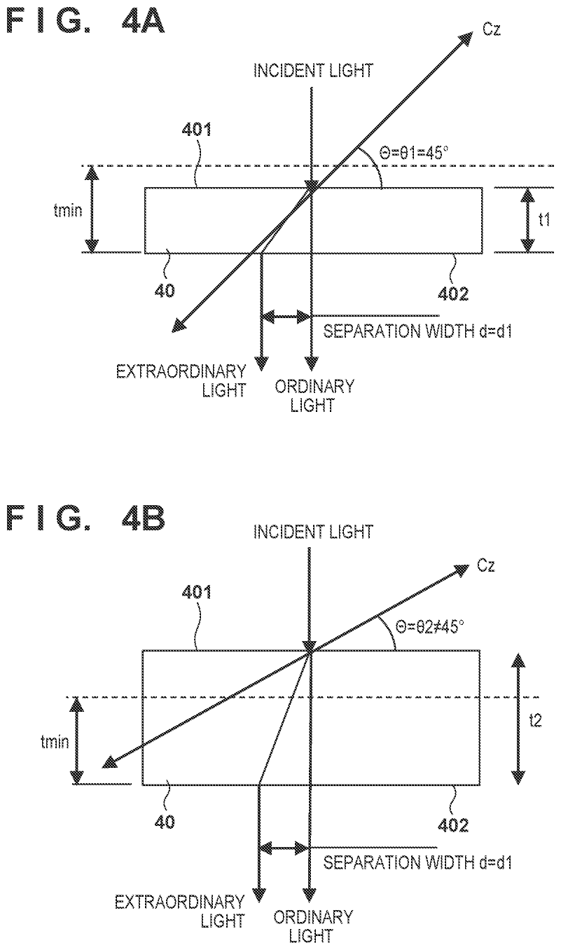

FIGS. 4A and 4B each schematically show the relationship between the separation characteristic of the quartz plate and the thickness of the quartz plate. FIG. 4A schematically shows the quartz plate 40 cut out from the quartz ingot at the angle θ=θ1=45° which is formed by the optical axis (Cz-axis) and the surfaces 401 and 402 when the required separation width d is represented by d=d1. Referring to FIG. 4A, the thickness t of the quartz plate 40 is represented by t=t1. FIG. 4B schematically shows the quartz plate 40 cut out from the quartz ingot at the angle θ=θ2≠45° when the required separation width d is represented by d=d1. Referring to FIG. 4B, the thickness t of the quartz plate 40 is represented by t=t2. In FIGS. 4A and 4B, tmin represents the minimum allowable value of t. More specifically, tmin represents the minimum thickness required for the quartz plate 40 to suppress deformation and damage of the quartz plate 40 caused by a stress applied from an external environment to the electronic component 100. When t1<tmin, the quartz plate 40 is cut out from the quartz ingot at θ2 that satisfies t2≥tmin, thereby making it possible to suppress deformation and damage of the quartz plate 40 while suppressing occurrence of color moiré and false color.

In this embodiment, θ2 (≠45°) that satisfies t2≥tmin can satisfy |3|°<θ2<|42|° or |48|°<θ2<|87|°. At this time, when θ2≤|10|° or |80|°≤θ2, t2 for satisfying the required separation width d is excessively large and the size of the electronic component 100 can increase. Thus, |10|°<θ2<|42|° or |48|°<θ2<|80|° is preferably satisfied.

The minimum allowable value tmin of the thickness of the quartz plate 40 can be defined in accordance with, for example, the outer size in the X direction and Y direction of the quartz plate 40, the material of the support 30, the adhesion condition between the support 30 and the quartz plate 40, and the like. In an example, the minimum allowable value tmin falls within the range of 0.2 mm (inclusive) to 0.5 mm (inclusive), and the thickness t2 of the quartz plate 40 preferably, accordingly falls within the range of 0.2 mm (inclusive) to 0.5 mm (inclusive). If the thickness t2 of the quartz plate 40 is smaller than 0.2 mm, the separation width d is very small, and thus the necessity for the quartz plate 40 to have a low-pass filter function may be low. Conversely, if t2 is larger than 0.5 mm, the size of the electronic component 100 can excessively increase.

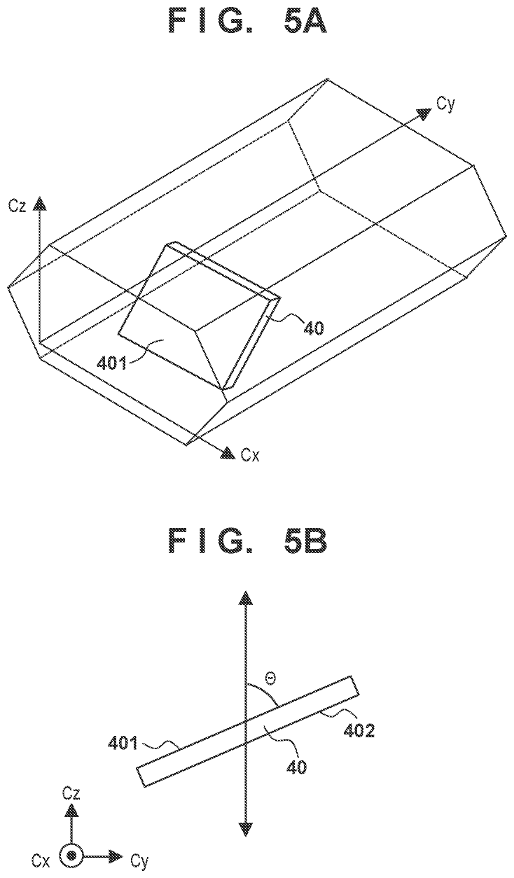

FIGS. 5A to 5D show an example of a method of cutting out the quartz plate 40 from the quartz ingot 400. Similar to FIG. 2A, FIG. 5A is a schematic view of the quartz ingot 400. FIG. 5B is a sectional view showing an example of the quartz plate 40 cut out from the quartz ingot 400. FIG. 5C is a plan view showing an example of the quartz plate 40 cut out from the quartz ingot 400. FIG. 5D is a plan view showing an example of the electronic component 100 in which the quartz plate 40 exemplified in FIGS. 5B and 5C is incorporated. The quartz plate 40 and its outer surface 401 and inner surface 402 can have a rectangular shape. The long side of the rectangle can be perpendicular to the optical axis (Cz-axis) of the quartz crystal forming the quartz plate 40 or the quartz ingot 400. In other words, the long side of the rectangle can be parallel to the Cx-axis. If the support 30 has a coefficient of linear expansion close to the coefficient of linear expansion of the quartz crystal in the direction perpendicular to the optical axis (Cz-axis) of the quartz crystal, the quartz plate 40 is preferably manufactured by this method of cutting out. By making the coefficients of linear expansion match each other between the long side direction of the quartz plate 40 and the support 30, the bonding reliability between the support 30 and the quartz plate 40 can be improved.

By adopting the above-described quartz plate 40 as a component of the electronic component 100, it is possible to suppress deformation, damage (for example, cracking or peeling), and the like of the quartz plate 40 and also suppress occurrence of color moiré and false color. The angle θ and the thickness t of the quartz plate 40 can be decided in accordance with the required separation width d. The angle θ and the thickness t of the quartz plate 40 may be decided in accordance with the number of quartz plates 40 cut out from the quartz ingot 400 and the like in addition to the required separation width d. As the thickness t of the quartz plate 40 is smaller, the absolute value of the angle θ is preferably larger. This is because as the absolute value of the angle θ is larger, the Young's modulus in the thickness direction of the quartz plate 40 is higher, and this is advantageous in suppressing deformation (distortion) of the quartz plate 40 caused by a change in internal pressure of the internal space 50.

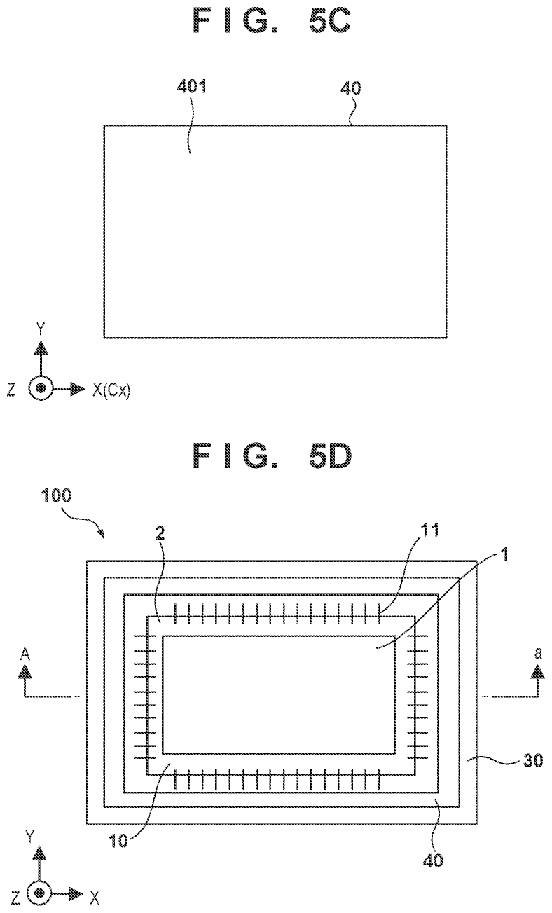

The second embodiment of the present disclosure will be described below. Matters not mentioned in the second embodiment can comply with the first embodiment. FIGS. 6A to 6D show an example of a method of cutting out a quartz plate 40 from a quartz ingot 400 according to the second embodiment. FIG. 6A is a schematic view of the quartz ingot 400, similar to FIGS. 2A and 5A. FIG. 6B is a sectional view showing an example of the quartz plate 40 cut out from the quartz ingot 400. FIG. 6C is a plan view showing an example of the quartz plate 40 cut out from the quartz ingot 400. FIG. 6D is a plan view showing an example of an electronic component 100 in which the quartz plate 40 exemplified in FIGS. 6B and 6C is incorporated. The quartz plate 40 and its outer surface 401 and inner surface 402 can have a rectangular shape. The short side of the rectangle can be perpendicular to the optical axis (Cz-axis) of a quartz crystal forming the quartz plate 40 or the quartz ingot 400. In other words, the short side of the rectangle can be parallel to the Cx-axis. If the support 30 has a coefficient of linear expansion close to a coefficient of linear expansion in a direction along a side (that is, a long side) having a length depending on an angle θ among the four sides of the quartz plate 40, the quartz plate 40 is preferably manufactured by this method of cutting out. By making the coefficients of linear expansion match each other between the long side direction of the quartz plate 40 and the support 30, the bonding reliability between the support 30 and the quartz plate 40 can be improved.

By adopting the above-described quartz plate 40 as a component of the electronic component 100, it is possible to suppress deformation, damage (for example, cracking or peeling), and the like of the quartz plate 40 and also suppress occurrence of color moiré and false color. The angle θ and a thickness t of the quartz plate 40 can be decided in accordance with a required separation width d. The angle θ and the thickness t of the quartz plate 40 may be decided in accordance with the number of quartz plates 40 cut out from the quartz ingot 400 and the like in addition to the required separation width d.

The third embodiment of the present disclosure will be described below. Matters not mentioned in the third embodiment can comply with the first or second embodiment. The third embodiment can provide a preferable example of a combination of an angle θ and a coefficient of linear expansion of a support 30.

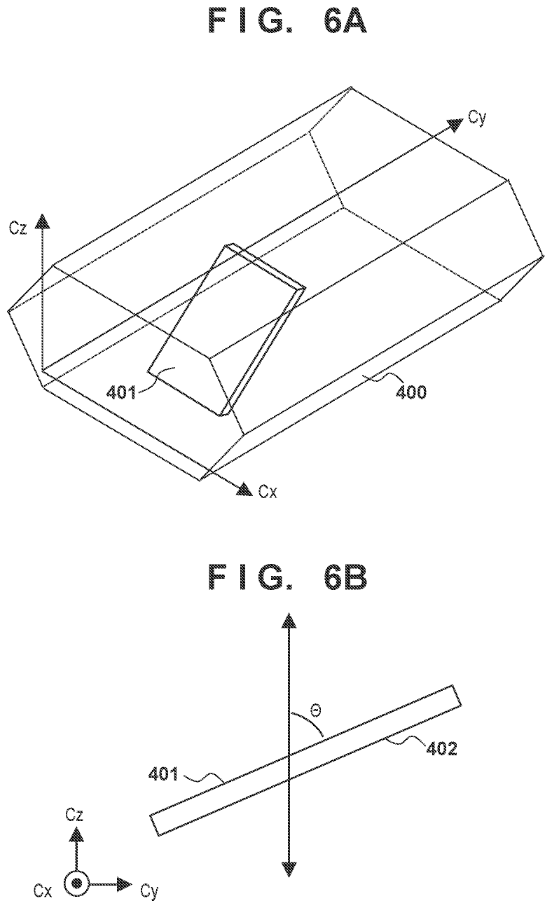

FIG. 7 is a sectional view showing an example of a quartz plate 40 cut out from a quartz ingot 400. In the third embodiment, the angle θ formed by an optical axis (Cz-axis), an outer surface 401, and an inner surface 402 (principal plane) satisfies θ<|42|°. In addition, in the third embodiment, the coefficient of linear expansion of the support 30 (a frame-like portion 32 thereof) falls within the range of 6 ppm (inclusive) to 10 ppm (exclusive). According to the third embodiment, with respect to a direction along a side having a length depending on the angle θ among the four sides of the quartz plate 40, the matching between the coefficient of linear expansion of the quartz plate 40 and that of the support 30 (the frame-like portion 32 thereof) is improved.

For example, in a case where θ=30° can be selected to implement a required separation width d, even if θ=60° is selected, the equal separation width d can be implemented. Therefore, there are two options of θ=30° and θ=60° as options for implementing the required separation width d. However, from the viewpoint of the bonding reliability between the support 30 and the quartz plate 40, θ=30° is preferably selected.

The fourth embodiment of the present disclosure will be described below. Matters not mentioned in the fourth embodiment can comply with the first or second embodiment. The fourth embodiment can provide a preferable example of a combination of an angle θ and a coefficient of linear expansion of a support 30.

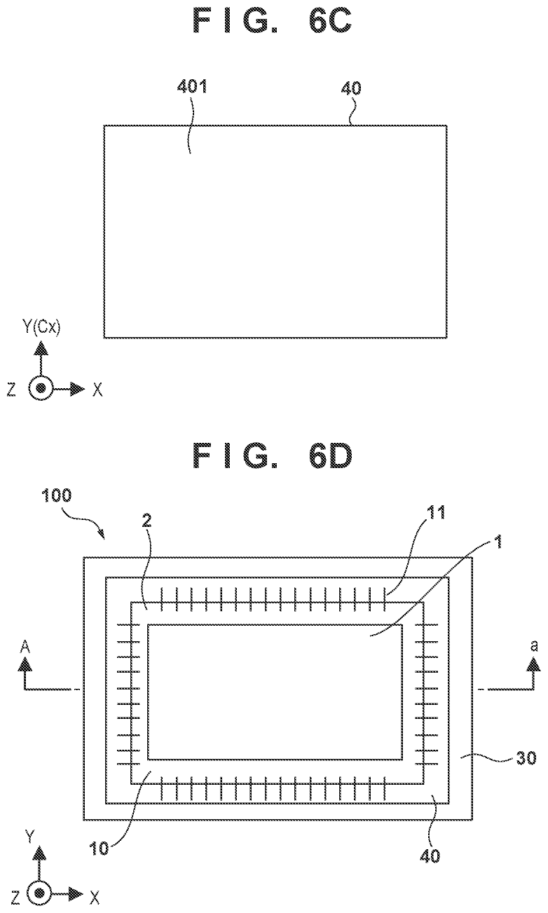

FIG. 8 is a sectional view showing an example of a quartz plate 40 cut out from a quartz ingot 400. In the fourth embodiment, the angle θ formed by an optical axis (Cz-axis), an outer surface 401, and an inner surface 402 (principal plane) satisfies θ>|48|°. In addition, in the fourth embodiment, the coefficient of linear expansion of the support 30 (a frame-like portion 32 thereof) falls within the range of 10 ppm (inclusive) to 14 ppm (exclusive). According to the fourth embodiment, with respect to a direction along a side having a length depending on the angle θ among the four sides of the quartz plate 40, the matching between the coefficient of linear expansion of the quartz plate 40 and that of the support 30 (the frame-like portion 32 thereof) is improved.

For example, in a case where θ=60° can be selected to implement a required separation width d, even if θ=30° is selected, the equal separation width d can be implemented. Therefore, there are two options of θ=30° and θ=60° as options for implementing the required separation width d. However, from the viewpoint of the bonding reliability between the support 30 and the quartz plate 40, θ=60° is preferably selected.

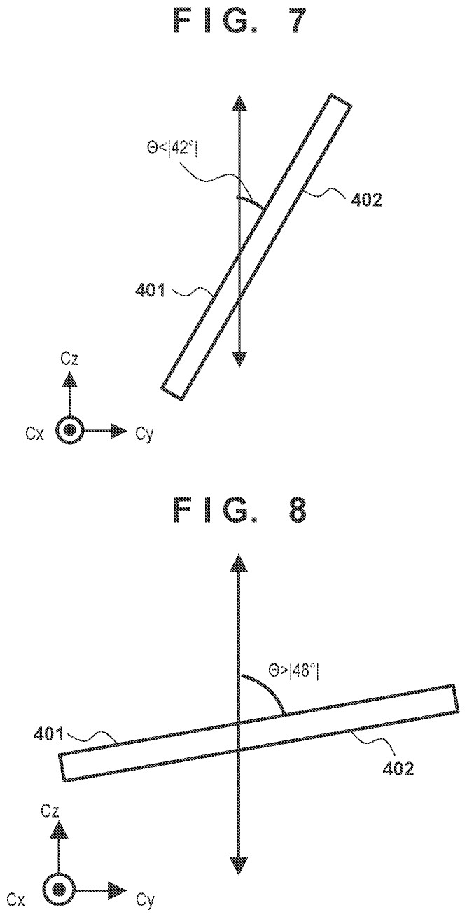

FIG. 9 exemplarily shows the arrangement of an apparatus 200 in which an electronic component 100 representing the first to fourth embodiments is incorporated. In a case where an electronic device 10 forming the electronic component 100 serves as an image capturing device, the electronic component 100 can be formed as an image sensor and the apparatus 200 can be formed as an image capturing apparatus. The concept of the image capturing apparatus includes an information processing apparatus (for example, a computer, a smartphone, and the like) having an image capturing function. In a case where the electronic device 10 forming the electronic component 100 serves as a display device, the electronic component 100 can be formed as a display panel, and the apparatus 200 can be formed as a display apparatus.

The apparatus 200 can include the electronic component 100 and a controller 210 that controls the electronic component 100. The apparatus 200 may further include a processor 220. For example, the processor 220 can be configured to process a signal output from the electronic component 100. Alternatively, the processor 220 can be configured to generate a signal and supply it to the electronic component 100.

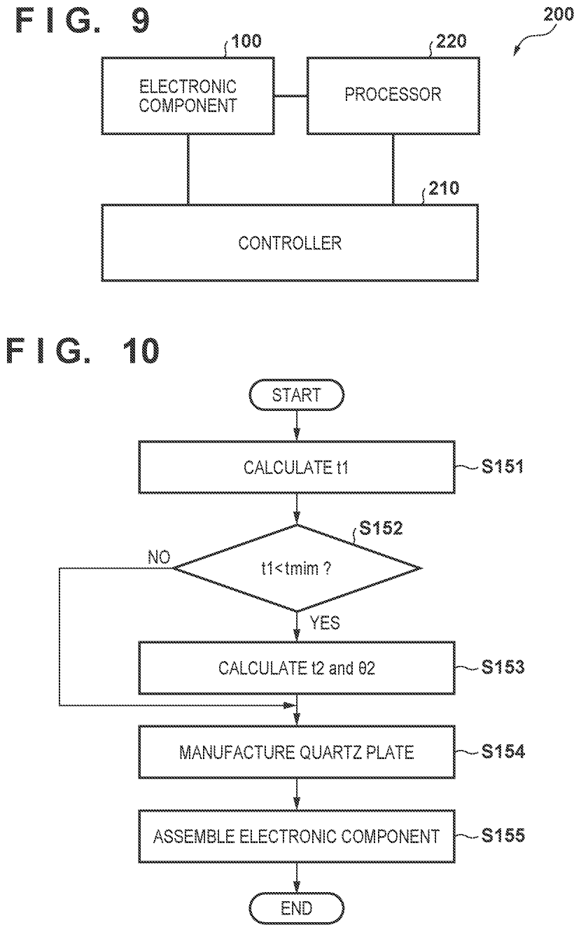

FIG. 10 exemplarily shows a method of manufacturing the electronic component 100. The method of manufacturing the electronic component 100 can include, for example, steps S151 to S155. In step S151 (calculation step), the value of t satisfying d=d1 and θ=450 can be calculated as t1. In steps S152 and S153 (decision step), if t1<tmin, the values of t and θ satisfying t≥tmin can be decided as t2 and θ2, respectively. In steps S152 and S153, tmin is preferably set to satisfy 0.2 mm≤tmin≤0.5 mm. In step S152, it is determined whether t<tmin is satisfied. If t<tmin is satisfied, step S153 is executed, and the values of t and θ satisfying t≥tmin can be decided as t2 and θ2, respectively, in step S153. If it is determined in step S152 that t<tmin is not satisfied, the process advances to step S154 by setting t=t1 and θ=45° as step S153.

If step S153 is executed, the quartz plate 40 can be manufactured from the quartz ingot 400 in accordance with t2 and θ2 in step S154 (manufacturing step). On the other hand, if step S153 is not executed, the quartz plate 40 can be manufactured from the quartz ingot 400 in accordance with t=t1 and θ=450 in step S154. In step S155 (assembly step), the electronic component 100 can be assembled so that the support 30 supports the electronic device 10 and the support 30 and the quartz plate 40 house the electronic device 10.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-151802, filed Sep. 22, 2022, which is hereby incorporated by reference herein in its entirety.

What is claimed is:

1. An electronic component comprising an electronic device and a container configured to house the electronic device, wherein
the container includes a support configured to support the electronic device, and a quartz plate having a principal plane facing the electronic device, and an angle θ formed by the principal plane and an optical axis of the quartz plate satisfies |3|°<θ<|42|° or |48|°<θ<|87|°.

2. The component according to claim 1, wherein a thickness of the quartz plate in a direction perpendicular to the principal plane is not less than 0.2 mm and is not more than 0.5 mm.

3. The component according to claim 1, wherein the principal plane has a rectangular shape, and a long side of the rectangle is perpendicular to the optical axis.

4. The component according to claim 1, wherein the principal plane has a rectangular shape, and a short side of the rectangle is perpendicular to the optical axis.

5. The component according to claim 1, wherein a coefficient of linear expansion of the support is not less than 6 ppm and is less than 10 ppm.

6. The component according to claim 5, wherein |3|°<θ<|42|° is satisfied.

7. The component according to claim 1, wherein a coefficient of linear expansion of the support is not less than 10 ppm and is less than 14 ppm.

8. The component according to claim 7, wherein |48|°<θ<|87|° is satisfied.

9. The component according to claim 1, wherein the electronic device serves as an image capturing device.

10. The component according to claim 1, wherein the electronic device serves as a display device.

11. An apparatus comprising:
an electronic component; and
a controller configured to control the electronic component,
wherein the electronic component includes an electronic device and a container configured to house the electronic device, and
the container includes a support configured to support the electronic device, and a quartz plate having a principal plane facing the electronic device, and an angle θ formed by the principal plane and an optical axis of the quartz plate satisfies |3|°<θ<|42|° or |48|°<θ<|87|°.

12. A method of manufacturing an electronic component including an electronic device and a container configured to house the electronic device,
the container including a support configured to support the electronic device, and a quartz plate having a principal plane facing the electronic device,
the method comprising:
calculating a value of t satisfying d=d1 and θ=45° as t1 in a case where t represents a thickness of the quartz plate in a direction perpendicular to the principal plane, d represents a separation width of the quartz plate, d1 represents a required separation width, and θ represents an angle formed by the principal plane and an optical axis of the quartz plate;
deciding values of t and θ satisfying t≥tmin as t2 and θ2, respectively, in a case where t1<tmin where tmin represents a minimum allowable value of t;
manufacturing the quartz plate from a quartz ingot in accordance with t2 and θ2; and
assembling the electronic component so that the support supports the electronic device and the support and the quartz plate house the electronic device.

13. The method according to claim 12, wherein in the deciding, tmin is set to satisfy 0.2 mm≤tmin≤0.5 mm.
